(19) United States
(12) Patent Application Publication
(10) Pub. No.: US 2007/0164395 A1
(43) Pub. Date: Jul. 19, 2007

(54) CHIP PACKAGE WITH BUILT-IN CAPACITOR STRUCTURE

(76) Inventors: Jiin-Shing Perng, Hsinchu County (TW); Shih-Hsien Wu, Taoyuan County (TW); Min-Lin Lee, Hsinchu City (TW); Shinn-Juh Lay, Hsinchu County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/308,493

(22) Filed: Mar. 30, 2006

(30) Foreign Application Priority Data
Jan. 19, 2006 (TW) 95102034

(51) Int. Cl. H01L 29/00

(52) U.S. Cl. 257/532; 257/924; 257/E23.057

(57) ABSTRACT

A chip package with built-in capacitor structure including an integrated circuit (IC) unit, a capacitor unit, a carrier and a molding compound is provided. The capacitor unit is disposed on the IC unit and includes a first metal foil, a second metal foil, and a dielectric layer disposed between the first metal foil and the second metal foil. The carrier is disposed on the surface away from the dielectric layer of the second metal foil. The first metal foil is electrically connected to the carrier, the second metal foil is electrically connected to the carrier, the IC unit is electrically connected to the carrier, the IC unit is electrically connected to the first metal foil, and the IC unit is electrically connected to the second metal foil. The molding compound is disposed on the carrier for fixing the IC unit, the capacitor unit and the carrier.

### CROSS-REFERENCE TO RELATED APPLICATION

This application claims the priority benefit of Taiwan application serial no. 95102034, filed on Jan. 19, 2006. All disclosure of the Taiwan application is incorporated herein by reference.

### BACKGROUND OF THE INVENTION

1. Field of Invention

The present invention relates to a chip package. More particularly, the present invention relates to a chip package with built-in capacitor structure, which has noise suppressing function.

2. Description of Related Art

Semiconductor industry is one of the rapidly advanced hi-tech industries in recent years. Along with the development of electronic technology and the births of different hi-tech electronic industries, electronic products of higher user-friendliness and better performance have been brought into the market continuously and the trend of the designs thereof is light, thin, short, and small. Presently, in the semiconductor process, LOC (lead on chip) chip package is a chip package having thin size, high electrical performance, and high heat dissipation rate.

FIG. 1 is a diagram of a conventional chip package with built-in capacitor structure, which has a lead frame carried on the chip. Referring to FIG. 1, the chip package 100 includes a chip 110, an adhesive layer 130, a lead frame 120, a plurality of leads 140, and a molding compound 150. The lead frame 120 has a plurality of pins 122 carried on the chip 110 through the adhesive layer 130, wherein the adhesive layer 130 has an opening 132 for exposing a part of the chip 110. The adhesive layer 130 is a double-sided adhesive tape, thus, the adhesive layer 130 can fix the relative position between the chip 110 and the lead frame 120. The leads 140 electrically connect the chip 110 to the lead frame 120 through the opening 132. The molding compound 150 is disposed on the lead frame 120 to further fix the chip 110 on the lead frame 120, wherein the material of the molding compound is plastic.

Since LOC chip package has such advantages as reduced molding compound area, simple fabricating procedure, easy mass production, and lower fabricating cost etc., it has become the mainstream memory package.

### SUMMARY OF THE INVENTION

Accordingly, the present invention is directed to provide a chip package with built-in capacitor structure, which has noise suppressing function.

The present invention provides a capacitor unit including a first metal foil, a second metal foil, and a dielectric layer. The dielectric layer is disposed between the first metal foil and the second metal foil.

According to an embodiment of the present invention, the capacitor unit further includes a first adhesive layer disposed on a surface away from the dielectric layer of the first metal foil.

According to an embodiment of the present invention, the capacitor unit further includes a second adhesive layer disposed on a surface away from the dielectric layer of the second metal foil.

The present invention provides a chip package with built-in capacitor structure, which includes an integrated circuit (IC) unit, a capacitor unit, a carrier, and a molding compound. The IC unit has an active surface. The capacitor unit is disposed on the active surface. The capacitor unit includes a first metal foil, a second metal foil, and a dielectric layer disposed between the first metal foil and the second metal foil. The carrier is disposed on a surface away from the dielectric layer of the second metal foil, wherein the first metal foil is electrically connected to the carrier, the second metal foil is electrically connected to the carrier, the IC unit is electrically connected to the carrier, the IC unit is electrically connected to the first metal foil, and the IC unit is electrically connected to the second metal foil. The molding compound is disposed on the carrier for fixing the IC unit, the capacitor unit, and the carrier.

According to an embodiment of the present invention, the chip package with built-in capacitor structure further includes a first adhesive layer disposed between the IC unit and the first metal foil.

According to an embodiment of the present invention, the chip package with built-in capacitor structure further includes a second adhesive layer disposed between the carrier and the second metal foil.

According to an embodiment of the present invention, in the chip package with built-in capacitor structure, the carrier includes at least one ground terminal and at least one power terminal; the ground terminals are electrically connected to the first metal foil, and the power terminals are electrically connected to the second metal foil.

According to an embodiment of the present invention, in the chip package with built-in capacitor structure, the carrier includes at least one ground terminal and at least one power terminal; the ground terminals are electrically connected to the second metal foil, and the power terminals are electrically connected to the first metal foil.

According to an embodiment of the present invention, the chip package with built-in capacitor structure further includes a solder mask layer disposed on a surface away from the capacitor unit of the carrier, and the solder mask layer has a plurality of openings exposing parts of the carrier.

According to an embodiment of the present invention, the chip package with built-in capacitor structure further includes a plurality of external terminals which are disposed in the openings and are electrically connected to the carrier.

The present invention provides a chip package with built-in capacitor structure, which includes an IC unit, a capacitor unit, a carrier, a plurality of leads, and a molding compound. The IC unit has an active surface. The capacitor unit is disposed on the active surface. The capacitor unit includes a first metal foil, a dielectric layer, and a second metal foil. The first metal foil is disposed on the active surface and has a first opening for exposing a part of the IC unit. The dielectric layer is disposed on a surface of the first metal foil and has a second opening connected to the first opening. The second metal foil is disposed on a surface away from the first metal foil of the dielectric layer. The second metal foil has a third opening which is connected to the second opening and exposes a part of the first metal foil together with the second opening. The carrier has a plurality of pins and is disposed on a surface away from the dielectric layer of the second metal foil. The leads are electrically connected between the first metal foil and the pins, between the second metal foil and the pins, between the IC unit and the pins, between the IC unit and the first metal foil, and between the IC unit and the second metal foil. The molding compound is disposed on the carrier for fixing the IC unit, the capacitor unit, and the carrier.

According to an embodiment of the present invention, the chip package with built-in capacitor structure further includes a first adhesive layer disposed between the first metal foil and the IC unit. The first adhesive layer has a fourth opening which is connected to the first opening and exposes a part of the IC unit together with the first opening.

According to an embodiment of the present invention, the chip package with built-in capacitor structure further includes a second adhesive layer disposed between the second metal foil and the carrier. The second adhesive layer has a fifth opening which is connected to the third opening and exposes a part of the second metal foil.

According to an embodiment of the present invention, in the chip package with built-in capacitor structure, the pins include at least one ground pin and at least one power pin. The ground pins are connected to the first metal foil through the leads, and the power pins are connected to the second metal foil through the leads.

According to an embodiment of the present invention, in the chip package with built-in capacitor structure, the pins include at least one ground pin and at least one power pin. The ground pins are connected to the second metal foil through the leads, and the power pins are connected to the first metal foil through the leads.

According to an embodiment of the present invention, the chip package with built-in capacitor structure further includes a solder mask layer disposed on a surface away from the second adhesive layer of the carrier, and the solder mask layer has a plurality of sixth openings for exposing parts of the pins.

According to an embodiment of the present invention, the chip package with built-in capacitor structure further includes a plurality of external terminals which are disposed in the sixth openings and are electrically connected to the pins.

According to an embodiment of the present invention, in the chip package with built-in capacitor structure, the molding compound is further filled in the first opening, the second opening, the third opening, the fourth opening, and the fifth opening for covering the leads.

The present invention provides a chip package with built-in capacitor structure, which includes an IC unit, a capacitor unit, a carrier, a plurality of leads, and a molding compound. The IC unit has an active surface. The capacitor unit is disposed on the active surface. The capacitor unit includes a first metal foil, a dielectric layer, and a second metal foil. The first metal foil is disposed on the active surface and has a first opening for exposing a part of the capacitor unit. The dielectric layer is disposed on a surface of the first metal foil and has a second opening connected to the first opening. The second metal foil is disposed on another surface away from the first metal foil of the dielectric layer. The second metal foil has a third opening which is connected to the second opening and exposes a part of the first metal foil together with the second opening. The carrier is disposed on a surface away from the dielectric layer of the second metal foil. The carrier includes a substrate and a patterned circuit layer. The substrate is disposed on the surface away from the dielectric layer of the second metal foil. The patterned circuit layer is disposed on a surface away from the second metal foil of the substrate. The leads are electrically connected between the first metal foil and the patterned circuit layer, between the second metal foil and the patterned circuit layer, between the IC unit and the patterned circuit layer, between the IC unit and the first metal foil, and between the IC unit and the second metal foil. The molding compound is disposed on the carrier for fixing the IC unit, the capacitor unit, and the carrier.

According to an embodiment of the present invention, in the chip package with built-in capacitor structure, the first adhesive layer is disposed between the first metal foil and the IC unit. The first adhesive layer has a fourth opening which is connected to the first opening and exposes a part of the IC unit together with the first opening.

According to an embodiment of the present invention, the chip package with built-in capacitor structure further includes a second adhesive layer disposed between the second metal foil and the carrier. The second adhesive layer has a fifth opening which is connected to the third opening and exposes a part of the second metal foil.

According to an embodiment of the present invention, in the chip package with built-in capacitor structure, the patterned circuit layer includes at least one ground pad and at least one power pad. The ground pads are connected to the first metal foil through the leads, and the power pads are connected to the second metal foil through the leads.

According to an embodiment of the present invention, in the chip package with built-in capacitor structure, the patterned circuit layer includes at least one ground pad and at least one power pad. The ground pads are connected to the second metal foil through the leads, and the power pads are connected to the first metal foil through the leads.

According to an embodiment of the present invention, the chip package with built-in capacitor structure further includes a solder mask layer disposed on a surface away from the substrate of the patterned circuit layer. The solder mask layer has a plurality of sixth openings for exposing the pads of the patterned circuit layer.

According to an embodiment of the present invention, the chip package with built-in capacitor structure further includes a plurality of external terminals which are disposed in the sixth openings and are electrically connected to the patterned circuit layer.

According to an embodiment of the present invention, in the chip package with built-in capacitor structure, the molding compound is further filled in the first opening, the second opening, the third opening, the fourth opening, and the fifth opening for covering the leads.

According to the present invention, a capacitor unit is disposed between a carrier and an IC unit, thus, the chip package with built-in capacitor structure in the present invention has the effect of decoupling.

In order to make the aforementioned and other objects, features and advantages of the present invention comprehensible, a preferred embodiment accompanied with figures is described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a diagram of a conventional chip package with built-in capacitor structure, which has a lead frame carried on the chip.

FIG. 2 is a diagram of a chip package with built-in capacitor structure according to an embodiment of the present invention.

FIG. 3 is a diagram of a chip package with built-in capacitor structure according to another embodiment of the present invention.

FIG. 4 is a diagram of a chip package with built-in capacitor structure according to yet another embodiment of the present invention.

### DESCRIPTION OF EMBODIMENTS

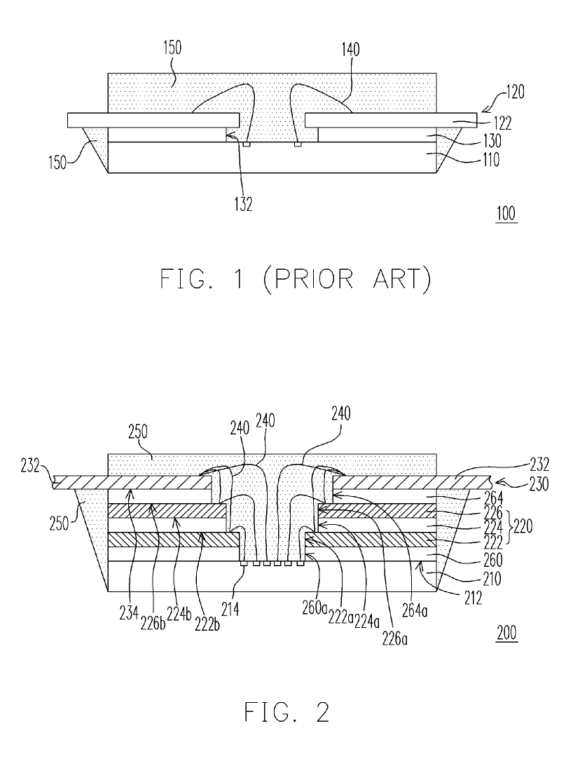

FIG. 2 is a diagram of a chip package with built-in capacitor structure according to an embodiment of the present invention. Referring to FIG. 2, the chip package 200 includes an integrated circuit (IC) unit 210, a capacitor unit 220, a carrier 230, a plurality of leads 240, and a molding compound 250. The IC unit 210 has an active surface 212 and a plurality of contacts 214. The capacitor unit 220 is disposed on the active surface 212. The capacitor unit 220 includes a first metal foil 222, a dielectric layer 224, and a second metal foil 226, wherein the first metal foil 222 is disposed on the active surface 212 and has a first opening 222a for exposing the contacts 214. The contacts 214 include a plurality of signal contacts, ground contacts, and power contacts.

As described above, the dielectric layer 224 is disposed on a surface 222b of the first metal foil 222 and has a second opening 224a connected to the first opening 222a. The second metal foil 226 is disposed on a surface 224b away from the first metal foil 222 of the dielectric layer 224 and has a third opening 226a which is connected to the second opening 224a and exposes the region of the first metal foil 222 adjacent to the first opening 222a together with the second opening 224a.

In the present embodiment, the first metal foil 222 of the capacitor unit 220 is disposed on the active surface 212 of the IC unit 210 through a first adhesive layer 260, wherein the material of the first adhesive layer 260 is, for example, adhesive colloid, double-sided adhesive tape, or other types of adhesive materials. The first adhesive layer 260 has a fourth opening 260a which is connected to the first opening 222a and exposes the contacts 214 of the IC unit 210 together with the first opening 222a.

The carrier 230 is disposed on the surface 226b away from the dielectric layer 224 of the second metal foil 226, wherein the carrier 230 has a plurality of signal terminals, a plurality of ground terminals, and a plurality of power terminals. In the present embodiment, the carrier 230 is a lead frame with a plurality of pins 232. The pins 232 include a plurality of signal pins, a plurality of ground pins, and a plurality of power pins, wherein the signal pins, ground pins, and power pins are respectively corresponding to the foregoing signal terminals, ground terminals, and power terminals.

In addition, in the present embodiment, the carrier 230 is carried on the second metal foil 226 through a second adhesive layer 264, wherein the material of the second adhesive layer 264 is, for example, adhesive colloid, double-sided adhesive tape, or other types of adhesive materials. The second adhesive layer 264 has a fifth opening 264a which is connected to the third opening 226a and exposes the region of the second metal foil 226 adjacent to the third opening 226a. In other words, the foregoing first opening 222a, second opening 224a, third opening 226a, fourth opening 260a, and fifth opening 264a are connected with each other and expose the contacts 214 of the IC unit 210 all together.

A part of the leads 240 is electrically connected between the first metal foil 222 and the pins 232 and between the second metal foil 226 and the pins 232. In particular, in the leads 240, the first metal foil 222 is electrically connected to the ground pins of the pins 232 through the leads 240, and the second metal foil 226 is electrically connected to the power pins of the pins 232 through the leads 240. The other leads 240 are electrically connected between the IC unit 210 and the pins 232, between the IC unit 210 and the first metal foil 222, and between the IC unit 210 and the second metal foil 226. It is remarkable that there is no lead 240 being electrically connected between the first metal foil 222 and the second metal foil 226.

Accordingly, while the chip package 200 is in operation, the IC unit 210 can obtain the ground voltage through the electrical connection thereof with the first metal foil 222 as well as through the electrical connection thereof with the ground pins of the pins 232. Besides, the IC unit 210 can obtain the power voltage through the electrical connection thereof with the second metal foil 226 as well as through the electrical connection thereof with the power pins of the pins 232.

Certainly, the present embodiment is not for limiting the present invention. In other embodiments of the present invention, the first metal foil 222 can be electrically connected to the power pins of the pins 232 through the leads 240, and the second metal foil 226 can be electrically connected to the ground pins of the pins 232 through the leads 240. Accordingly, while the chip package 200 is in operation, the IC unit 210 can obtain the power voltage through the electrical connection thereof with the first metal foil 222 as well as through the electrical connection thereof with the power pins of the pins 232. In addition, the IC unit 210 can obtain the ground voltage through the electrical connection thereof with the second metal foil 226 as well as through the electrical connection thereof with the ground pins of the pins 232.

The molding compound 250 is disposed on the carrier 230 for fixing the IC unit 210, the capacitor unit 220, and the carrier 230. Besides, the molding compound 250 can be further filled into the first opening 222a, the second opening 224a, the third opening 226a, the fourth opening 260a, and the fifth opening 264a for covering the leads 240.

It is remarkable that the present embodiment is not for limiting the number of the capacitor units in the present invention. In other embodiments of the present invention, the chip package can have a plurality of capacitor units, wherein the capacitor units are overlapped between the carrier and the IC unit, and the relative position between two adjacent capacitor units is fixed through an adhesive layer.

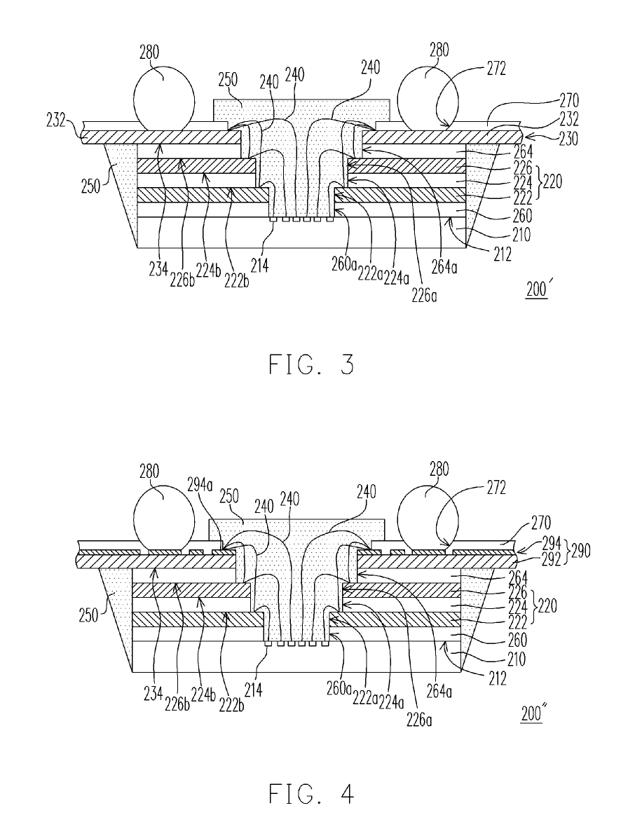

FIG. 3 is a diagram of a chip package with built-in capacitor structure according to another embodiment of the present invention. The main difference between the chip package 200′ and the chip package 200 is that the chip package 200′ further includes a solder mask layer 270 and a plurality of external terminals 280 disposed on a surface 234 away from the second adhesive layer 264 of the carrier 230. The solder mask layer 270 has a plurality of sixth openings 272 for exposing parts of the pins 232. The external terminals 280 are disposed in the sixth openings 272 and are electrically connected to the corresponding pins 232, wherein the external terminals 280 are, for example, solder balls or other conductors. Accordingly, the chip package 200′ can be electrically connected to other electronic devices through the external terminals 280.

Moreover, the embodiment described above is not for limiting the type of the carrier in the chip package of the present invention. Besides being a lead frame, the carrier used in the chip package of the present invention can also be formed by a substrate and a patterned circuit layer. FIG. 4 is a diagram of a chip package with built-in capacitor structure according to yet another embodiment of the present invention. Since the chip package 200″ is similar to the chip package 200, the components thereof will not be described here again. The carrier 290 of the chip package 200″ includes a substrate 292 and a patterned circuit layer 294. The substrate 292 is disposed on the surface 234 away from the dielectric layer 224 of the second metal foil 226. The patterned circuit layer 294 is disposed on a surface away from the dielectric layer 224 of the substrate 292. The patterned circuit layer 294 has a plurality of pads 294a, which include a plurality of signal pads, a plurality of ground pads, and a plurality of power pads, wherein the signal pads, ground pads, and power pads are respectively the signal terminals, ground terminals, and power terminals of the carrier.

A part of the leads 240 in the chip package 200″ is electrically connected between the first metal foil 222 and the pads 294a and between the second metal foil 226 and the pads 294a. In particular, in the leads 240, the first metal foil 222 is electrically connected to the ground pads of the pads 294a through the leads 240, and the second metal foil 226 is electrically connected to the power pads of the pads 294a through the leads 240. The other leads 240 are electrically connected between the IC unit 210 and the pads 294a, between the IC unit 210 and the first metal foil 222, and between the IC unit 210 and the second metal foil 226. It is remarkable that there is no lead 240 being electrically connected between the first metal foil 222 and the second metal foil 226.

Accordingly, while the chip package 200″ is in operation, the IC unit 210 can obtain the ground voltage through the electrical connection thereof with the first metal foil 222 as well as through the electrical connection thereof with the ground pads of the pads 294a. Besides, the IC unit 210 can obtain the power voltage through the electrical connection thereof with the second metal foil 226 as well as through the electrical connection thereof with the power pads of pads 294a.

Certainly, the present embodiment is not for limiting the present invention. In other embodiments of the present invention, the first metal foil 222 can be electrically connected to the power pads of the pads 294a through the leads 240, and the second metal foil 226 can be electrically connected to the ground pads of the pads 294a through the leads 240. Accordingly, while the chip package 200″ is in operation, the IC unit 210 can obtain the power voltage through the electrical connection thereof with the first metal foil 222 as well as through the electrical connection thereof with the power pads of the pads 294a. Besides, the IC unit 210 can obtain the ground voltage through the electrical connection thereof with the second metal foil 226 as well as through the electrical connection thereof with the ground pads of the pads 294a.

Certainly, the chip package 200″ further includes a solder mask layer 270 and a plurality of external terminals 280 disposed on a surface away from the second adhesive layer 264 of the carrier 290. The solder mask layer 270 has a plurality of sixth openings 272 for exposing parts of the patterned circuit layer 294. The external terminals 280 are disposed in the sixth openings 272 and are electrically connected to the patterned circuit layer 294, wherein the external terminals 280 are, for example, solder balls or other conductors.

In overview, according to the present invention, a capacitor unit is disposed between a carrier and an IC unit, thus the chip package with built-in capacitor structure in the present invention has the effect of decoupling.

In addition, while the chip package with built-in capacitor structure in the present invention is in operation, since the IC unit can obtain the ground voltage and the power voltage through the electrical connections thereof with the first metal foil and with the second metal foil, the chip package with built-in capacitor structure in the present invention has excellent power distribution path.

Furthermore, the first metal foil and the second metal foil are good conductors of heat, thus, while the chip package with built-in capacitor structure in the present invention is in operation, the heat produced by the chip can be transmitted to the other parts of the chip package with built-in capacitor structure through the first metal foil and the second metal foil. Thus, the chip package with built-in capacitor structure in the present invention has more uniform temperature distribution compared with conventional chip packages.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A capacitor unit, comprising:
a first metal foil;
a second metal foil; and
a dielectric layer, disposed between the first metal foil and the second metal foil.

2. The capacitor unit as claimed in claim 1 further comprising a first adhesive layer disposed on a surface away from the dielectric layer of the first metal foil.

3. The capacitor unit as claimed in claim 1 further comprising a second adhesive layer disposed on a surface away from the dielectric layer of the second metal foil.

4. A chip package with built-in capacitor structure, comprising:
an integrated circuit (IC) unit, having an active surface;
a capacitor unit, disposed on the active surface, the capacitor unit comprising:
a first metal foil, disposed on the active surface;
a second metal foil; and
a dielectric layer, disposed between the first metal foil and the second metal foil;
a carrier, disposed on a surface away from the dielectric layer of the second metal foil, wherein the first metal foil is electrically connected to the carrier, the second metal foil is electrically connected to the carrier, the IC unit is electrically connected to the carrier, the IC unit is electrically connected to the first metal foil, and the IC unit is electrically connected to the second metal foil; and
a molding compound, disposed on the carrier for fixing the IC unit, the capacitor unit, and the carrier.

5. The chip package as claimed in claim 4 further comprising a first adhesive layer disposed between the IC unit and the first metal foil.

6. The chip package as claimed in claim 4 further comprising a second adhesive layer disposed between the carrier and the second metal foil.

7. The chip package as claimed in claim 4, wherein the carrier comprises at least one ground terminal and at least one power terminal, the ground terminals are electrically connected to the first metal foil, and the power terminals are electrically connected to the second metal foil.

8. The chip package as claimed in claim 4, wherein the carrier comprises at least one ground terminal and at least one power terminal, the ground terminals are electrically connected to the second metal foil, and the power terminals are electrically connected to the first metal foil.

9. The chip package as claimed in claim 4 further comprising a solder mask layer disposed on a surface away from the capacitor unit of the carrier, the solder mask layer having a plurality of openings for exposing parts of the carrier.

10. The chip package as claimed in claim 9 further comprising a plurality of external terminals disposed in the openings and electrically connected to the carrier.

11. A chip package with built-in capacitor structure, comprising:
an IC unit, having an active surface;
a capacitor unit, disposed on the active surface, the capacitor unit comprising:
a first metal foil, disposed on the active surface, the first metal foil having a first opening exposing a part of the IC unit;
a dielectric layer, disposed on a surface of the first metal foil, the dielectric layer having a second opening connected to the first opening;
a second metal foil, disposed on a surface away from the first metal foil of the dielectric layer, the second metal foil having a third opening, wherein the third opening is connected to the second opening and exposes a part of the first metal foil together with the second opening;
a carrier, having a plurality of pins, the carrier being disposed on the surface away from the dielectric layer of the second metal foil;
a plurality of leads, electrically connected between the first metal foil and the pins, between the second metal foil and the pins, between the IC unit and the pins, between the IC unit and the first metal foil, and between the IC unit and the second metal foil; and
a molding compound, disposed on the carrier for fixing the IC unit, the capacitor unit, and the carrier.

12. The chip package as claimed in claim 11 further comprising a first adhesive layer disposed between the first metal foil and the IC unit, the first adhesive layer having a fourth opening, wherein the fourth opening is connected to the first opening and exposes a part of the IC unit together with the first opening.

13. The chip package as claimed in claim 11 further comprising a second adhesive layer disposed between the second metal foil and the carrier, the second adhesive layer has a fifth opening, wherein the fifth opening is connected to the third opening and exposes a part of the second metal foil.

14. The chip package as claimed in claim 11, wherein the pins comprise at least one ground pin and at least one power pin, the ground pins are connected to the first metal foil through the leads, and the power pins are connected to the second metal foil through the leads.

15. The chip package as claimed in claim 11, wherein the pins comprise at least one ground pin and at least one power pin, the ground pins are connected to the second metal foil through the leads, and the power pins are connected to the first metal foil though the leads.

16. The chip package as claimed in claim 11 further comprising a solder mask layer disposed on a surface away from the second adhesive layer of the carrier, the solder mask layer having a plurality of sixth openings for exposing parts of the pins.

17. The chip package as claimed in claim 11 further comprising a plurality of external terminals disposed in the sixth openings and electrically connected to the pins.

18. The chip package as claimed in claim 11, wherein the molding compound is further filled in the first opening, the second opening, the third opening, the fourth opening, and the fifth opening for covering the leads.

19. A chip package with built-in capacitor structure, comprising:
an IC unit, having an active surface;
a capacitor unit, disposed on the active surface, the capacitor unit comprising:
a first metal foil, disposed on the active surface, the first metal foil having a first opening exposing a part of the capacitor unit;
a dielectric layer, disposed on a surface of the first metal foil, the dielectric layer having a second opening connected to the first opening;
a second metal foil, disposed on another surface away from the first metal foil of the dielectric layer, the second metal foil having a third opening, wherein the third opening is connected to the second opening and exposes a part of the first metal foil together with the second opening;
a carrier, disposed on the surface away from the dielectric layer of the second metal foil, the carrier comprising:
a substrate, disposed on the surface away from the dielectric layer of the second metal foil;
a patterned circuit layer, disposed on the surface away from the second metal foil of the substrate;
a plurality of leads, electrically connected between the first metal foil and the patterned circuit layer, between the second metal foil and the patterned circuit layer, between the IC unit and the patterned circuit layer, between the IC unit and the first metal foil, and between the IC unit and the second metal foil; and
a molding compound, disposed on the carrier for fixing the IC unit, the capacitor unit, and the carrier.

20. The chip package as claimed in claim 19 further comprising a first adhesive layer disposed between the first metal foil and the IC unit, the first adhesive layer having a fourth opening, wherein the fourth opening is connected to the first opening and exposes a part of the IC unit together with the first opening.

21. The chip package as claimed in claim 19 further comprising a second adhesive layer disposed between the second metal foil and the carrier, the second adhesive layer having a fifth opening, wherein the fifth opening is connected to the third opening and exposes a part of the second metal foil.

22. The chip package as claimed in claim 19, wherein the patterned circuit layer comprises at least one ground pad and at least one power pad, the ground pads are connected to the first metal foil through the leads, and the power pads are connected to the second metal foil through the leads.

23. The chip package as claimed in claim 19, wherein the patterned circuit layer comprises at least one ground pad and at least one power pad, the ground pads are connected to the second metal foil through the leads, and the power pads are connected to the first metal foil through the leads.

24. The chip package as claimed in claim 19 further comprising a solder mask layer disposed on a surface away from the substrate of the patterned circuit layer, the solder mask layer having a plurality of sixth openings for exposing the pads of the patterned circuit layer.

25. The chip package as claimed in claim 19 further comprising a plurality of external terminals disposed in the sixth openings and electrically connected to the patterned circuit layer.

26. The chip package as claimed in claim 19, wherein the molding compound is further filled in the first opening, the second opening, the third opening, the fourth opening, and the fifth opening for covering the leads.
